(19) United States
(12) Patent Application Publication
(10) Pub. No.: US 2017/0025179 A1
(43) Pub. Date: Jan. 26, 2017

(54) NON-VOLATILE MEMORY DEVICE FOR REDUCING BIT LINE RECOVERY TIME

(71) Applicant: MACRONIX INTERNATIONAL CO., LTD., Hsin-chu City (TW)

(72) Inventors: Atsuhiro Suzuki, Hsinchu City (TW); Chih-Wei Lee, New Taipei City (TW); Shaw-Hung Ku, Hsinchu City (TW)

(21) Appl. No.: 14/808,745

(22) Filed: Jul. 24, 2015

(51) Int. Cl. G11C 16/24; G11C 16/04; G11C 16/10

(52) U.S. Cl. CPC G11C 16/24; G11C 16/10; G11C 16/0483; G11C 16/0466

(57) ABSTRACT

Methods and apparatuses are contemplated herein for reducing bit-line recovery time of nonvolatile memory devices. In an example embodiment, a nonvolatile memory device comprises a 3D array of non-volatile memory cells, including a plurality of blocks, each block comprising a plurality of NAND strings, each of the NAND strings coupled to a bit line and word lines, the word lines arranged orthogonally to the NAND strings and establishing the memory cells at cross-points between surfaces of the NAND strings and the word lines, and a first set of discharge transistors positioned at an edge of the 3D array, coupled to a corresponding bit line, and configured for BL discharge, and a second set of discharge transistors positioned such that a first portion of BL potential is discharged through the first set of discharge transistors and a second portion through the second set.

### TECHNOLOGICAL FIELD

Example embodiments of the present invention relate generally to non-volatile memory devices and, more particularly, to high density non-volatile memory devices in which multiple planes of memory cells are arranged to provide a three-dimensional 3D array.

### BACKGROUND

For conventional NAND or 3D NAND chip architecture, a sense-amplifier (SA) in age-buffer (PB) is usually located at the bottom of memory chip, and is utilized to sense low power signals from a bit-line (BL) representing a data bit (e.g., 0 or 1) stored in a memory cell and amplify the voltage. During programming and verifying, the BL potential needs to have recovered completely to make sensing reliable. However, as design architecture continues to decrease in size, the BL resistive-capacitive (RC) delay worsens, resulting in longer recovery time and thereby degrading memory chip performance.

Accordingly, there is a need in the art to increase the performance of a non-volatile memory device by improving BL recovery time to meet the demand for high performance NAND flash. Moreover, improved BL recovery may enable increased accuracy in the verifying performance.

### BRIEF SUMMARY OF EXEMPLARY EMBODIMENTS

In accordance with embodiments of the present invention, a nonvolatile memory device is provided that can increase the performance of a memory device by improving BL recovery time.

In some embodiments, an apparatus for controlling a non-volatile memory device may be provided, the apparatus comprising a substrate, and a 3D array of non-volatile memory cells, the 3D array including a plurality of blocks, each block comprising (1) a plurality of NAND strings of nonvolatile memory cells, each of plurality of NAND strings coupled to a bit line (BL), (2) one or more word lines, the one or more word lines arranged orthogonally to the plurality of NAND strings, the one more word lines establishing the nonvolatile memory cells at cross-points between surfaces of the plurality of NAND strings and the one or more word lines, and a first set of discharge transistors, the first set of transistors positioned at an edge of the 3D array and coupled to a corresponding bit line, the first set of discharge transistors configured for BL discharge, and a second set of discharge transistors, the second set of discharge transistors comprising one or more discharge transistors, the second set of discharge transistors positioned such that a first portion of BL potential is discharged through the first set of discharge transistors and a second portion of BL potential is discharged through the second set of discharge transistors.

In some embodiments, the second set of discharge transistors couple a pre-defined NAND string to the substrate enabling discharging of the BL potential through the NAND string to the substrate. In some embodiments, the second set of discharge transistors are coupled to a BL on a side opposite the first set of discharge transistors enabling discharging of the BL potential from both sides of the NAND string.

In some embodiments, the second set of discharge transistors is a single common transistor coupling the NAND string to the substrate enabling discharging of the BL potential through the NAND string to the substrate. In some embodiments, the second set of discharge transistors is a plurality of discharging transistors, coupling each of a plurality of NAND string cells to the substrate enabling discharging of the BL potential through the NAND string to the substrate.

In some embodiments, the second set of discharge transistors is positioned at or near a mid-point of the BLs such that a maximum distance of the BL required for discharging is halved. In some embodiments, the apparatus further comprises a third set of discharge transistors, wherein the second set of discharge transistors is positioned at a far block or a side opposite the first set of discharge transistors and the third set of discharge transistors is positioned in a block at or near the middle of the memory array.

In some embodiments, the apparatus further comprises a control circuit configured for performing a bit line recovery operation in which the bit lines are discharged to a ground voltage level. In some embodiments, the non-volatile memory device comprises a NAND flash memory. In some embodiments, the 3D array includes one of a floating gate device or a charge trapping device.

In some embodiments, a non-volatile memory device may be provided, the memory device comprising a 3D array of non-volatile memory cells, the 3D array including a plurality of blocks, each block comprising (1) a plurality of NAND strings of nonvolatile memory cells, each of plurality of NAND strings coupled to a bit line (BL), (2) one or more word lines, the one or more word lines arranged orthogonally to the plurality of NAND strings, the one more word lines establishing the nonvolatile memory cells at cross-points between surfaces of the plurality of NAND strings and the one or more word lines, and a first set of discharge transistors, the first set of transistors positioned at an edge of the 3D array and coupled to a corresponding bit line, the first set of discharge transistors configured for BL discharge, and a second set of discharge transistors, the second set of discharge transistors comprising one or more discharge transistors, the second set of discharge transistors positioned such that a first portion of BL potential is discharged through the first set of discharge transistors and a second portion of BL potential is discharged through the second set of discharge transistors.

In some embodiments, the second set of discharge transistors couple a pre-defined NAND string to the substrate enabling discharging of the BL potential through the NAND string to the substrate. In some embodiments, the second set of discharge transistors are coupled to a BL on a side opposite the first set of discharge transistors enabling discharging of the BL potential from both sides of the NAND string.

In some embodiments, the second set of discharge transistors is a single common transistor coupling the NAND string to the substrate enabling discharging of the BL potential through the NAND string to the substrate. In some embodiments, the second set of discharge transistors is a plurality of discharging transistors, coupling each of a plurality of NAND string cells to the substrate enabling discharging of the BL potential through the NAND string to the substrate.

In some embodiments, the second set of discharge transistors is positioned at or near a mid-point of the BLs such that a maximum distance of the BL required for discharging is halved. In some embodiments, the memory device further comprises a third set of discharge transistors, wherein the second set of discharge transistors is positioned at a far block or a side opposite the first set of discharge transistors and the third set of discharge transistors is positioned in a block at or near the middle of the memory array.

In some embodiments, the memory device further comprises a control circuit configured for performing a bit line recovery operation in which the bit lines are discharged to a ground voltage level. In some embodiments, the non-volatile memory device comprises a NAND flash memory.

In some embodiments, a method of programming a nonvolatile semiconductor memory device may be provided, the method comprising providing a 3D array of non-volatile memory cells, the 3D array including a plurality of blocks, each block comprising (1) a plurality of NAND strings of nonvolatile memory cells, each of plurality of NAND strings coupled to a bit line (BL), (2) one or more word lines, the one or more word lines arranged orthogonally to the plurality of NAND strings, the one more word lines establishing the nonvolatile memory cells at cross-points between surfaces of the plurality of NAND strings and the one or more word lines, and providing a first set of discharge transistors, the first set of transistors positioned at an edge of the 3D array and coupled to a corresponding bit line, the first set of discharge transistors configured for BL discharge, and providing a second set of discharge transistors, the second set of discharge transistors comprising one or more discharge transistors, the second set of discharge transistors positioned such that a first portion of BL potential is discharged through the first set of discharge transistors and a second portion of BL potential is discharged through the second set of discharge transistors, and performing a bit line recovery operation in which the bit lines are discharged to a ground voltage level utilizing the first set of discharge transistors and the second set of discharge transistors.

The above summary is provided merely for purposes of summarizing some example embodiments to provide a basic understanding of some aspects of the invention. Accordingly, it will be appreciated that the above-described embodiments are merely examples and should not be construed to narrow the scope or spirit of the invention in any way. It will be appreciated that the scope of the invention encompasses many potential embodiments in addition to those here summarized, some of which will be further described below.

### BRIEF DESCRIPTION OF THE SEVERAL VIEWS OF THE DRAWINGS

Having thus described certain example embodiments of the present disclosure in general terms, reference will now be made to the accompanying drawings, which are not necessarily drawn to scale, and wherein:

FIG. 1 illustrates a block diagram of a semiconductor device including a control circuit and a series of nonvolatile memory elements, in accordance with example embodiments of the present invention.

FIG. 2A a schematic diagram of a conventional two-dimensional NAND structure, in accordance with example embodiments of the present invention;

FIG. 2B shows a conventional three-dimensional application of a two-dimensional NAND structure, in accordance with example embodiments of the present invention; and

FIG. 3 illustrates a block diagram of a two-dimensional NAND structure in accordance with example embodiments of the present invention;

FIG. 4 shows a graph illustrating the program/verify operation and BL recovery of a memory device, in accordance with example embodiments of the present invention;

FIG. 5 illustrates a block diagram of a two-dimensional NAND structure with corresponding graphs illustrating the BL recovery, in accordance with example embodiments of the present invention;

FIG. 6A illustrates a convention 3D NAND architecture, in accordance with example embodiments of the present invention;

FIG. 6B shows a 2D perspective of FIG. 6A with a first set of discharge transistors, in accordance with example embodiments of the present invention;

FIG. 7A shows a 2D perspective of a NAND structure, in accordance with example embodiments of the present invention;

FIG. 7B shows a 3D perspective of a NAND structure, in accordance with example embodiments of the present invention

FIGS. 8A-8C show block diagrams of a memory array, in accordance with example embodiments of the present invention;

FIG. 9 shows an operation table of selected blocks, in accordance with example embodiments of the present invention;

FIGS. 10A-10B show graphs illustrating a comparison of BL recovery time, in accordance with example embodiments of the present invention;

FIG. 11 shows a flowchart of operations performed to improve BL recovery in a nonvolatile memory device, in accordance with example embodiments of the present invention

FIG. 12 shows a schematic diagram of a NAND structure in accordance with example embodiments of the present invention;

FIG. 13 shows various top views of exemplary vertical channel layouts and blocks, in accordance with example embodiments of the present invention; and

FIGS. 14A and 14B show various top views of exemplary discharge transistor layouts, in accordance with example embodiments of the present invention.

### DETAILED DESCRIPTION

Some embodiments of the present invention will now be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

As used here, a “non-volatile memory device” refers to a semiconductor device which is able to store information even when the supply of electricity is removed. Non-volatile memory includes, without limitation, Mask Read-Only Memory, Programmable Read-Only Memory, Erasable Programmable Read-Only Memory, Electrically Erasable Programmable Read-Only Memory, and Flash Memory.

As used herein, a “substrate” may include any underlying material or materials upon which a device, a circuit, an epitaxial layer, or a semiconductor may be formed. Generally, a substrate may be used to define the layer or layers that underlie a semiconductor device or even forms the base layer of a semiconductor device. The substrate may include one or any combination of silicon, doped silicon, germanium, silicon germanium, semiconductor compounds, or other semiconductor materials.

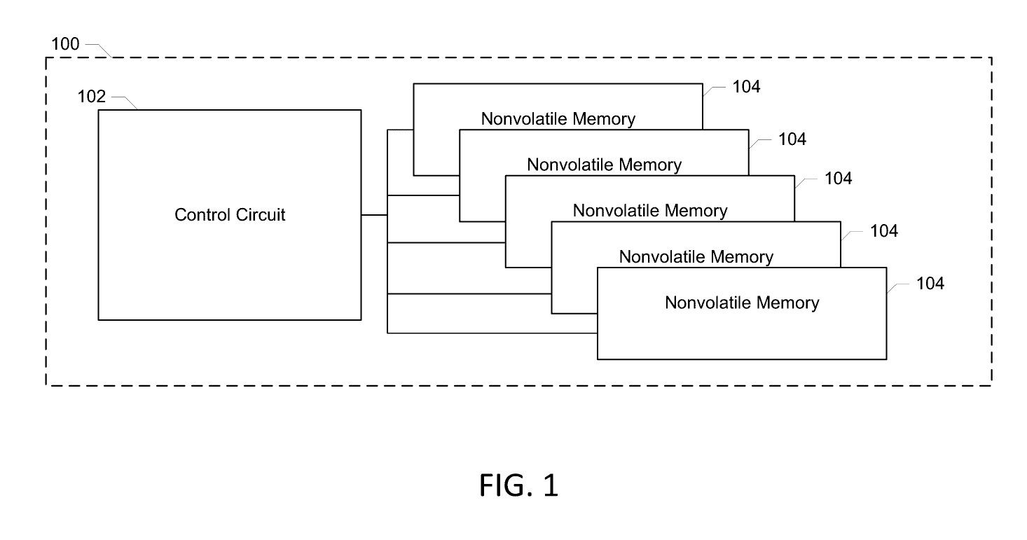

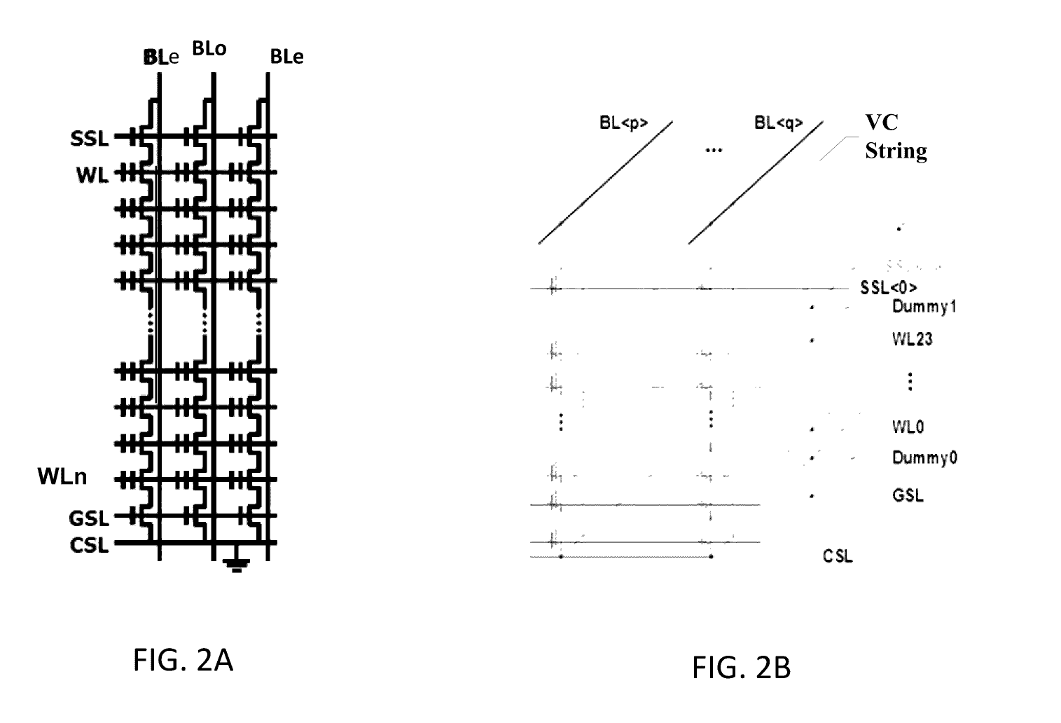

Turning now to FIG. 1, a block diagram of an example semiconductor device 100 is provided. This example semiconductor device includes both a control circuit 102 and a series of nonvolatile memories 104. The control circuit 102 communicates with each of the nonvolatile memories 104 and is configured to direct the read, program, erase, and other operations applied to the memory elements. In turn, each nonvolatile memory 104 may include a matrix of memory cells arranged in rows and columns. For example, FIG. 2A shows a schematic diagram of a conventional two-dimensional NAND structure.

Each memory cell in the matrix includes a transistor structure having a gate, a drain, a source, and a channel defined between the drain and the source. Each memory cell is located at an intersection between a word line and a bit line, wherein the gate is connected to the word line, the drain is connected to the bit line, and the source is connected to a source line, which in turn is connected to common ground. The gate of a conventional flash memory cell generally comprises a dual-gate structure, including a control gate and a floating gate, wherein the floating gate is suspended between two oxide layers to trap electrons that program the cell. In some embodiments, each nonvolatile memory 104 may include a three-dimensional memory. FIG. 2B shows a conventional three-dimensional application of the two-dimensional NAND structure shown in FIG. 2A.

### Conventional Architecture

As can be seen in FIG. 2A, in the conventional NAND flash architecture, the cells are connected in series (e.g., typically in groups of 16 or 32). For example, an example matrix of memory cells is illustrated. This matrix of memory cells is part of a block within a nonvolatile memory device (such as one of nonvolatile memories 104 described in connection with FIG. 1, above). Each block of the nonvolatile memory device includes a plurality of word lines (of which WL . . . and WLₙ are illustrated in FIG. 2A) that intersect a sequence of odd and even bit lines. In FIG. 2A, the illustrated portion of the block illustrates one odd bit lines (BLₒ) and two even bit lines (BLₑ). A memory cell is located at each intersecting point of a word line and a bit line. Because there are n word lines and three bit lines shown, FIG. 2A illustrates 3n total memory cells.

Two selection transistors are placed at the edges of the stack, to ensure the connections to ground (through MGSL) and to the BL (through MSSL). When a cell is read, its gate is set to 0V, while the other gates of the stack are biased with a high voltage (typically 4-5 V), so that they work as pass-transistor, regardless of their threshold voltage. An erased NAND flash cell has a negative threshold voltage. On the contrary, a programmed cell has a positive threshold voltage but, in any case, less than 4V. In practice, driving the selected gate with 0V, the series of all the cells will sink current if the addressed cell is erased, otherwise no current is sunk if the cell is programmed.

FIG. 2B shows a convention three-dimensional application of the two-dimensional NAND structure shown in FIG. 2A. As shown, each NAND layer, one of which is shown in FIG. 2A, comprises a plurality of word lines (of which WL0 . . . and WL23 are illustrated in FIG. 2B) that intersect a sequence of odd and even bit lines (of which BL<p> . . . BL<q> are illustrated in FIG. 2B). Moreover, each NAND layer comprises a single SSL (SSL<0>, SSL<1>, and SSL<7> are illustrated in FIG. 2B).

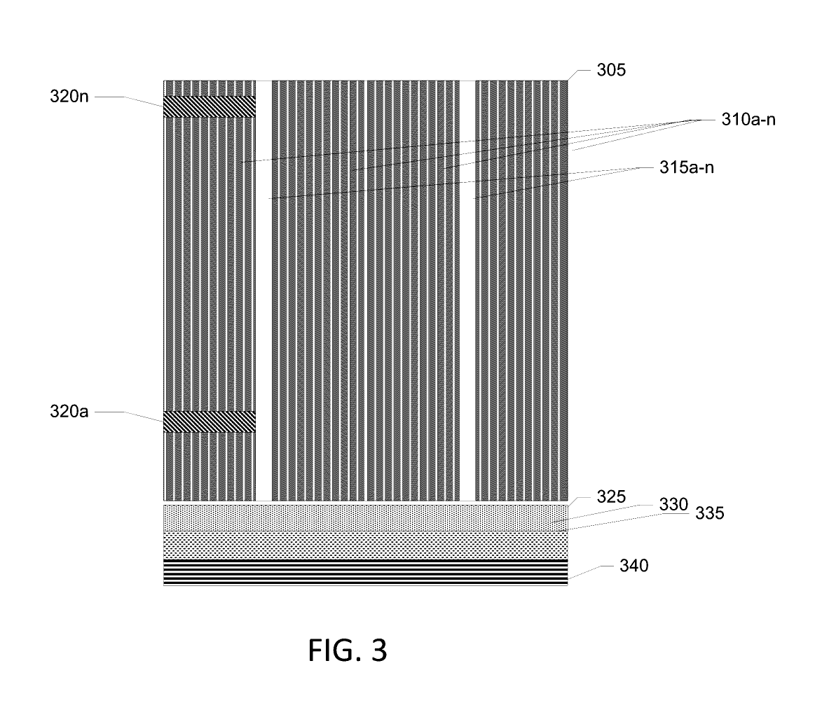

FIG. 3 illustrates a conventional NAND architecture (e.g., high density and simple architecture with a cell efficiency >65%). As shown, the NAND comprises a memory array region 305 including memory arrays 310a-310n, WL decoder and driver regions 315a-315n, and blocks 320a-320n. Furthermore, the NAND comprises a sense amplifier and page buffer region 325, which comprises a page driver and buffer 330. The NAND further comprises a peripheral and charge pump 335 and a data I/O pad 340.

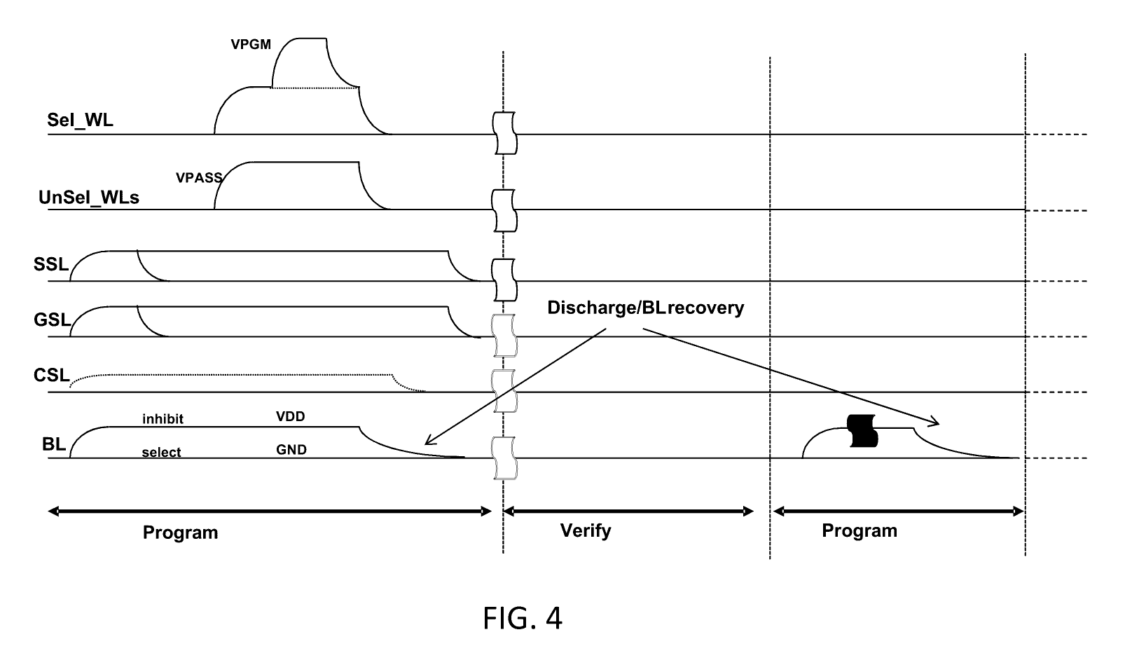

As can be seen, some portions of memory arrays 310a-310n are positioned further from the sense amplifier and page buffer region 325, which may result in an increased discharge time for, for example, the portions of the bit lines positioned at those portions of the memory arrays. FIG. 4 illustrates a BL discharging scheme comprising a number of axis. Notably, the BL axis shows a discharge/BL recovery graph. As shown, in some embodiments, a longer recovery time may be required for making a BL stable. In some embodiments, BL RC may become continue to increase as NAND structures continue to decrease in size, which may affect Program/Verify/Read performance. Moreover, BL RC may be critical for ABL lockout.

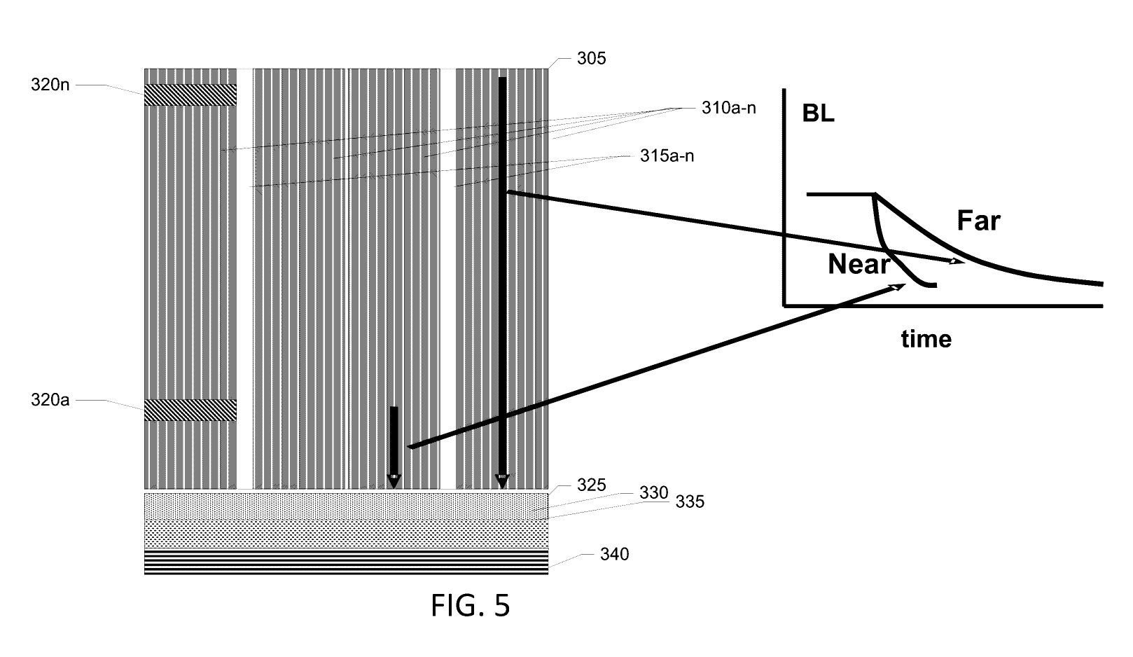

FIG. 5 illustrates the same NAND architecture of FIG. 4 and further illustrates the BL discharging distance and the associated time to discharge. For example, as shown, discharging of BLs in the memory array may be performed where portions of the BLs are positioned far from and/or near to the page driver and buffer region 325. In some embodiments, a time that discharging may take may be dependent on the distance from the discharging transistor. For example, as shown, the time for discharging from a position nearer to the page driver and buffer region 325 is significantly less than the time for discharging from a position further away from the page driver and buffer region 325.

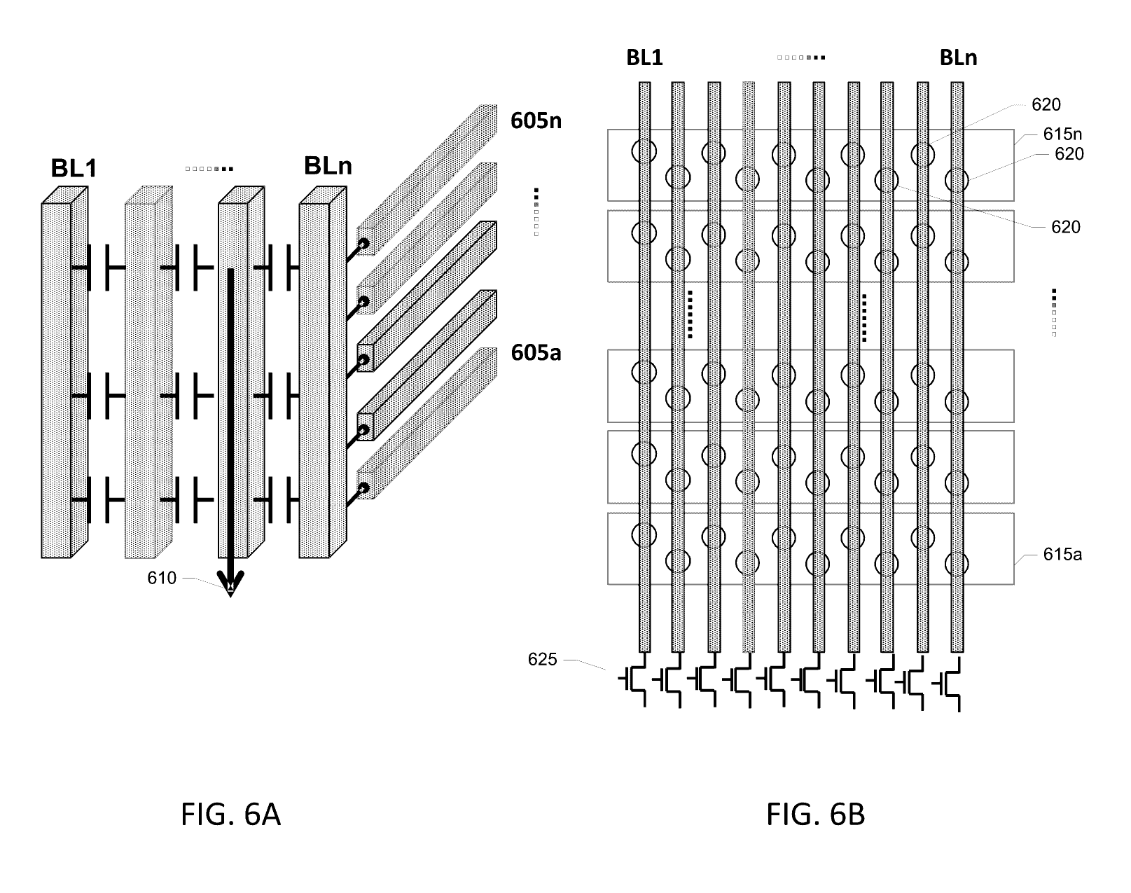

FIG. 6A shows a 3D illustration of a conventional NAND structure comprising BLs (of which BL1-BLn are shown) and a Vertical Channel (VC) array (of which 605a-605n are shown). As shown, the BLs and the vertical NANDs or VC strings are arranged orthogonally. The arrow 610 represents the discharging of the BLs. FIG. 6B shows a 2D illustration of a conventional 3D NAND structure comprising BLs BL1-BLn and a plurality of vertical NAND arrays arranged in blocks 615a-615n. Each block comprises VC arrays 620. For simplicity, each VC array is not labeled but is contained in a block and intersected by a BL. Furthermore, FIG. 6B shows the SA PB transistors 625 used to discharge the BLs. Again, as shown, some portions of BLs are positioned further from the SA PB transistors, which are located in the sense amplifier and page buffer region 325, which may result in an increased discharge time for, for example, the portions of the bit lines positioned at those portions of the memory arrays.

### Inventive Architecture

In some embodiments disclosed herein, two types of improved discharge transistor design that may be utilized in, for example, 3D NAND memory are disclosed. Each improved discharge transistor design may create an additional path for discharging a BL, and thus BL potential may be recovered more rapidly. For example, in some embodiments, one or more discharge transistors may be positioned on the side of the memory array and be configured to discharge BL potential through a NAND string to the substrate. In some embodiments, one or more additional discharge transistors may be positioned on the opposite side of original SA PB transistors such that BL potential may be discharged from both sides of the memory array.

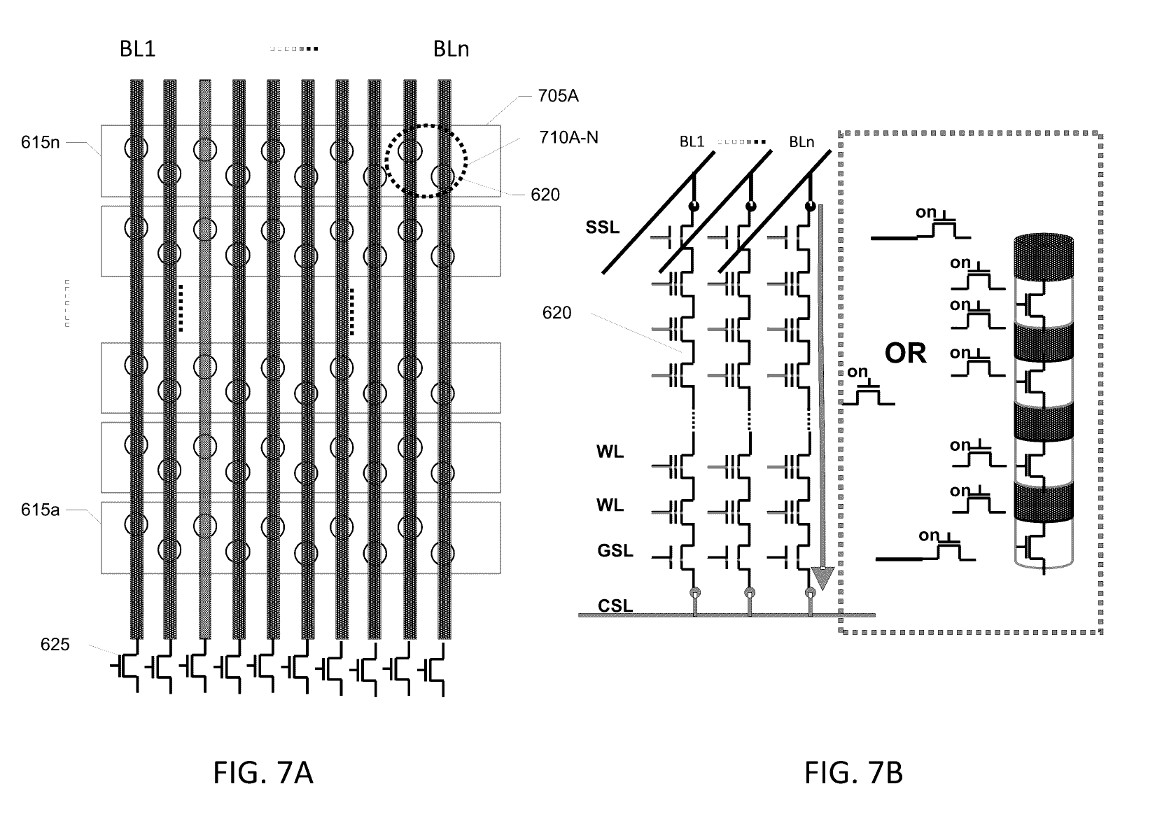

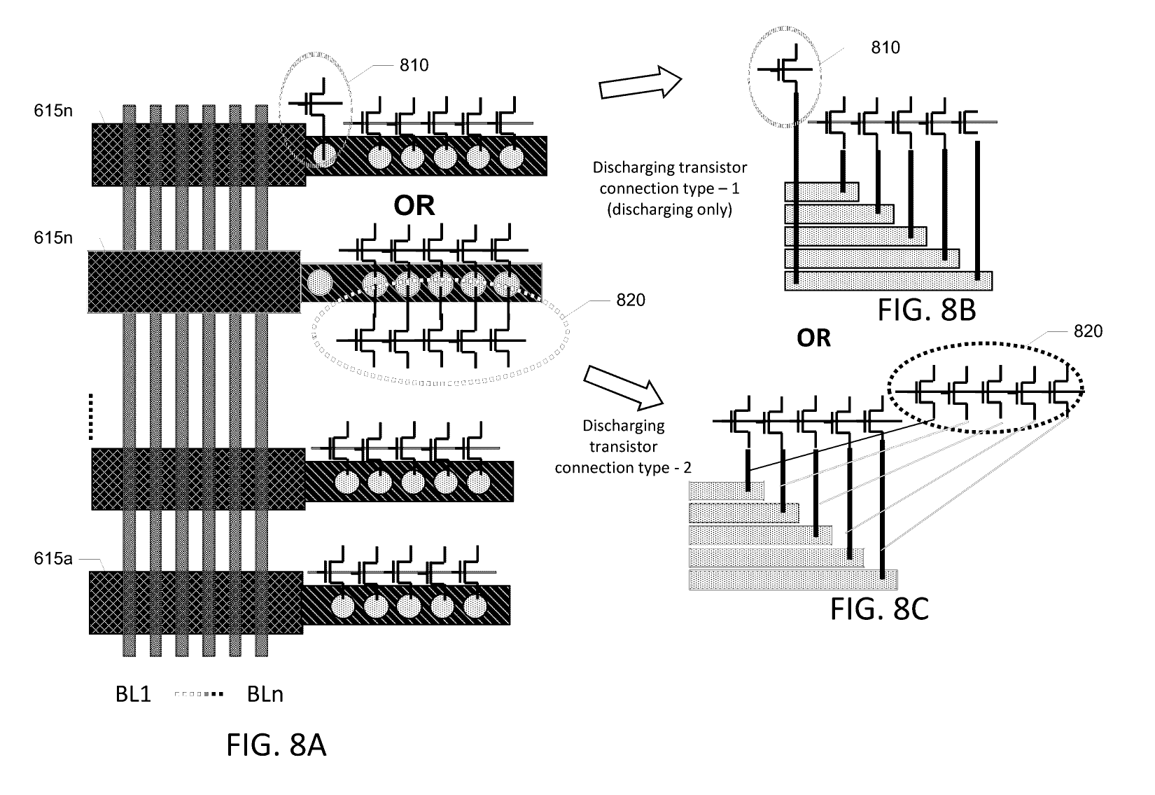

FIG. 7A shows one exemplary embodiment of the present invention. Specifically, FIG. 7A shows a plurality of BLs arranged orthogonally to the blocks, the blocks comprising VC arrays. On one end of the BLs, the S/A PB transistors 625 used to discharge the BLs are shown. Moreover, one the side of the memory array positioned further from the SA PB transistors 625 used to discharge the BLs, block 705 is shown. Block 705A comprises VC arrays 710A-710N, which may be utilized for BL discharge in addition to the SA PB transistors 625. For example, as shown in FIG. 7B, a VC array far from SA PB may be utilized as a discharge transistor. FIG. 7B shows a 3D view of FIG. 7A, specifically block 705A, which shows the transistors in the NAND string/WLs, notably VC arrays 710A-710N of block 705A. In some embodiments, WL Driver Transistors turn off during program/verify/read except for BL recovery time. As shown, in some embodiments, one or two discharging transistor connection types may be utilized, a discharging transistor connection type 1 or a discharging transistor connection type 2, which are further discussed with reference to FIGS. 8A-8C.

FIG. 8A shows two different discharging transistor connection types (e.g., type 1 and type 2) that may be provided in some embodiments of the present invention. Specifically, FIG. 8A shows a memory array comprising a plurality of block 615a-615n. The memory array further shows a discharging transistor connection type 1 (discharging only) and a discharging transistor connection type 2. As shown, for example in FIG. 8B, in some embodiments, a discharging transistor connection type 1 810 may be utilized. Discharging transistor connection type 1 810 may utilized as a single transistor coupled to each of a plurality of VC arrays. Whereas, in other embodiments, a discharging transistor connection type 2 820 may be utilized. For example, FIG. 8C shows a discharging transistor connection type 2 820. A discharging transistor connection type 2 820 may utilized as a separate discharging transistor coupled to each of a plurality of VC arrays.

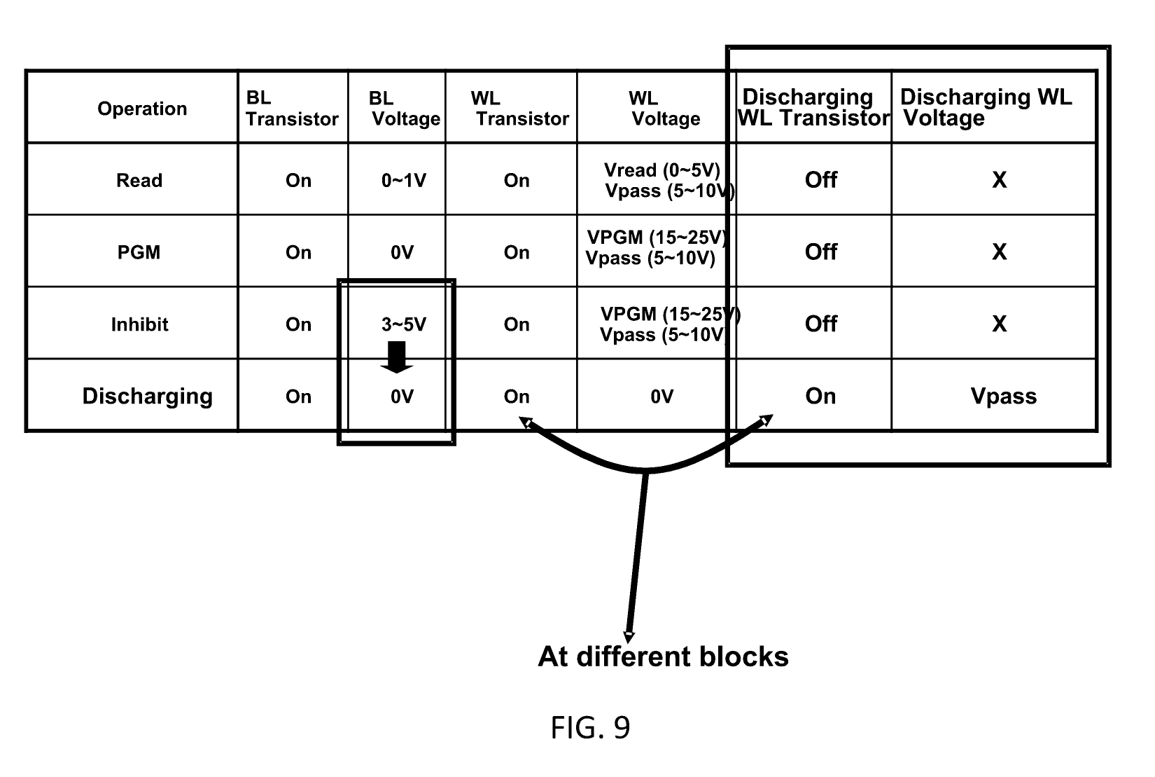

FIG. 9 shows an operation table. As discussed above, the BL line voltage should be discharged or recovered to, or near to, ground before a next operation may be performed for, for example, sensing accuracy and speed concerns. As shown in FIG. 9, BL voltage, during discharge from, for example, a program inhibit operation, goes to 0V. To do this, the WL transistor may be turned on and set to 0V. In a second block, a discharging WL transistor may be turned on and set to Vpass. That is, a VC array in a second block may be utilized to assist BL discharging.

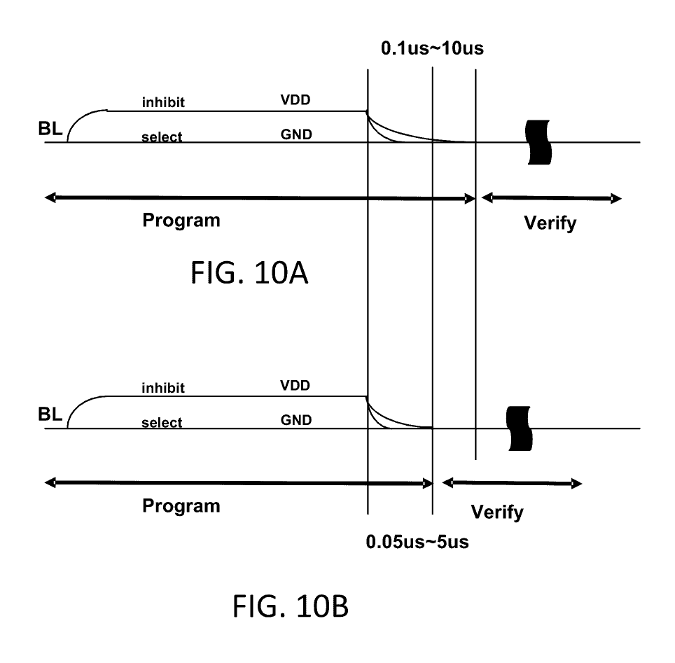

FIGS. 10A and 10B show waveform diagrams illustrating a comparison between the BL discharge time of a conventional method versus the BL discharge time of embodiments of the present invention. FIG. 10A, showing a waveform diagram of, for example, conventional methods of BL discharge, indicates that the BL discharge time of, for example the conventional method described above has a longer discharging/BL recovery time (e.g., 0.1 μs˜10 μs). Whereas, as shown in the waveform diagram FIG. 10B, indicate that embodiments of the present invention enable BL discharging in 0.05 μs˜5 μs.

### Operation

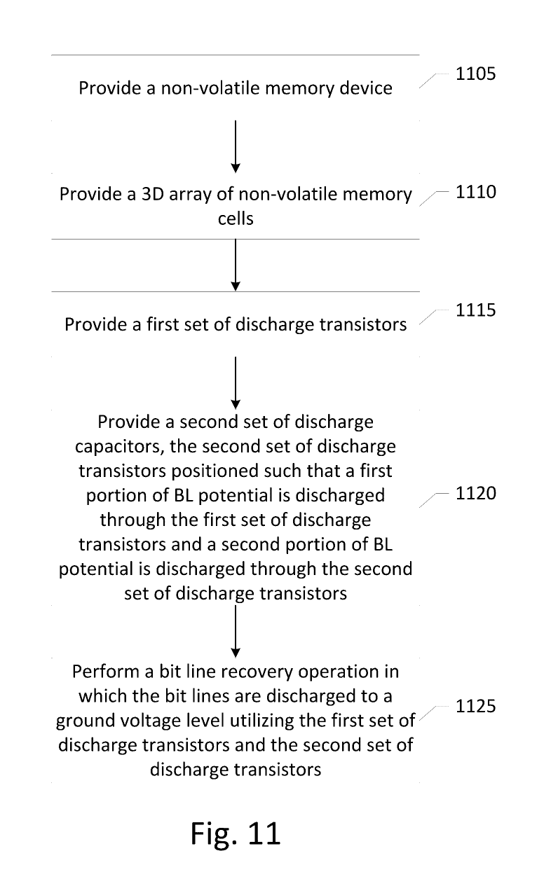

Turning now to FIG. 11, a flowchart is shown showing the operations performed to improve BL recovery in a nonvolatile memory device. In operation 1105, a nonvolatile memory device is provided. This nonvolatile memory device may include an on-chip control circuit, as illustrated in FIG. 1. In some embodiments, the nonvolatile memory device may also include a sense-amplifier and page buffer, also illustrated in FIG. 1. At operation 1110, a 3D array of non-volatile memory cells may be provided. In some embodiments, the 3D array may comprise a plurality of blocks. Each block may then comprise, for example, a plurality of NAND strings of nonvolatile memory cells, each of plurality of NAND strings coupled to a BL. Each block may further comprise one or more word lines, the one or more word lines arranged orthogonally to the plurality of NAND strings and the one more word lines establishing the nonvolatile memory cells at cross-points between surfaces of the plurality of NAND strings and the one or more word lines. At operation 1115, a first discharge switch, or in some embodiments, a first set of discharge transistors may be provided. In some embodiments, the first set of discharge transistors may be positioned at an edge of the 3D array and coupled to a corresponding bit line, the first set of discharge transistors configured for BL discharge. In some exemplary embodiments, the first discharge switch (or the first set of discharge transistors) may be located in a page buffer region of a memory device or the like.

At operation 1120, a second discharge switch or a second set of discharge transistors may be provided. The second discharge switch or the second set of discharge transistors may comprise one or more discharge transistors. In some embodiments, the second set of discharge transistors may be positioned such that a first portion of BL potential is discharged through the first set of discharge transistors and a second portion of BL potential is discharged through the second set of discharge transistors.

At operation 1125, a bit line recovery operation may be performed in which the bit lines are discharged to a ground voltage level utilizing the first set of discharge transistors and the second set of discharge transistors.

### Variations

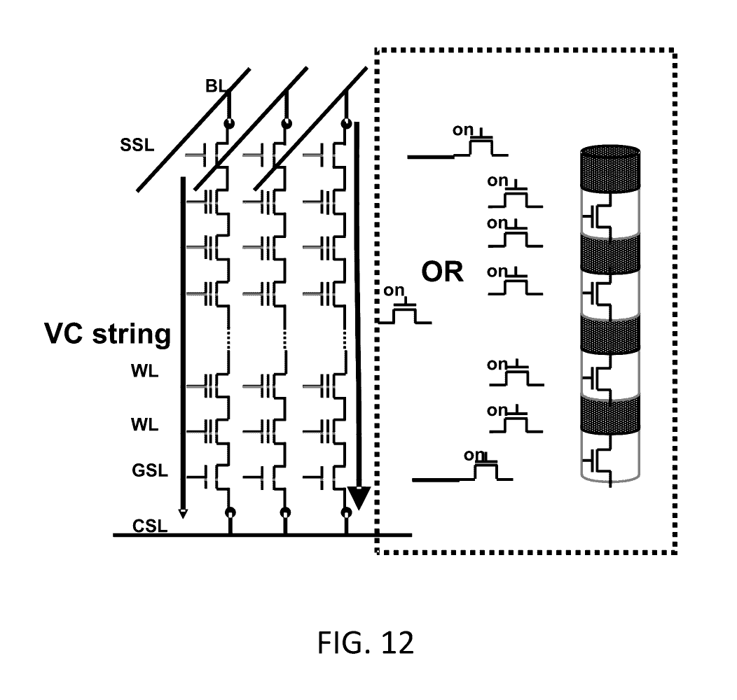

It should be understood that while the present invention is described for clarity using a VC array, for example, positioned away from the SA PB transistors, as shown in FIG. 12, the nonvolatile memory device may utilize one common transistor to control all the string cells or may be utilized two or more transistors to control all the string cells. For example, FIG. 12 illustrates an exemplary embodiment in which any number of transistors may be utilized in BL discharge. That is, VC array far from SA PB transistors may be utilized as additional discharge transistors. WL driver transistors may turn off during program/verify/read except for BL recovery time and one common transistor to control all strings or multiple transistors to control all stings may be utilized.

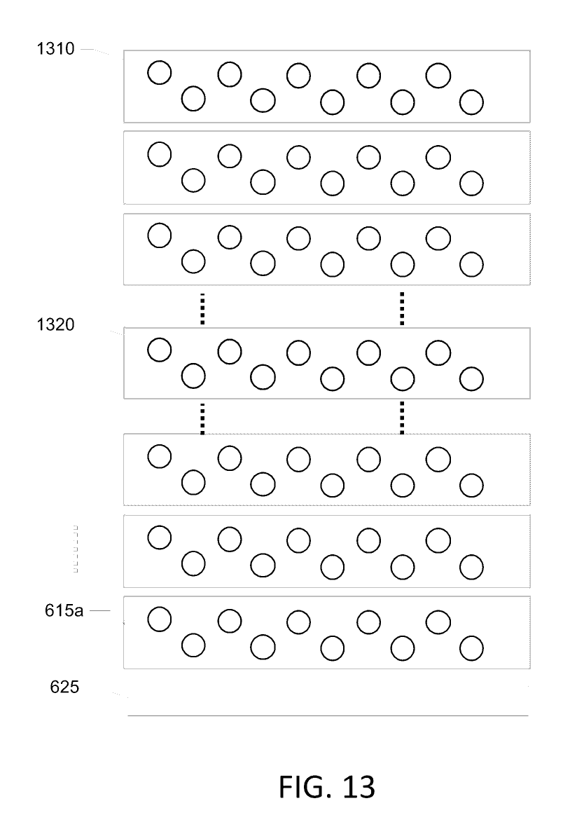

Furthermore, while some embodiments of present invention are described using a VC array, for example, positioned away from the S/A PB transistors 625, in some embodiments of the present invention, one or more VC arrays positioned elsewhere, for example in the middle, or near the middle of the memory array may be utilized. For example, FIG. 13 shows an exemplary embodiment in which the VC arrays in a block 1320 positioned in the middle of the memory array may be utilized in BL discharge. Moreover, while some embodiments of the present invention show VC arrays in a single block being utilized as discharge transistors, in other embodiments, any number of blocks may provide VC arrays that may be utilized as discharge transistors. For example, FIG. 12 shows that both VC arrays from a block 1310 positioned far from S/A PB transistors 625 and VC arrays in a block 1320 positioned nearer to SA PB transistors 625 (e.g., in the middle of the memory array) may be utilized additional discharge transistors.

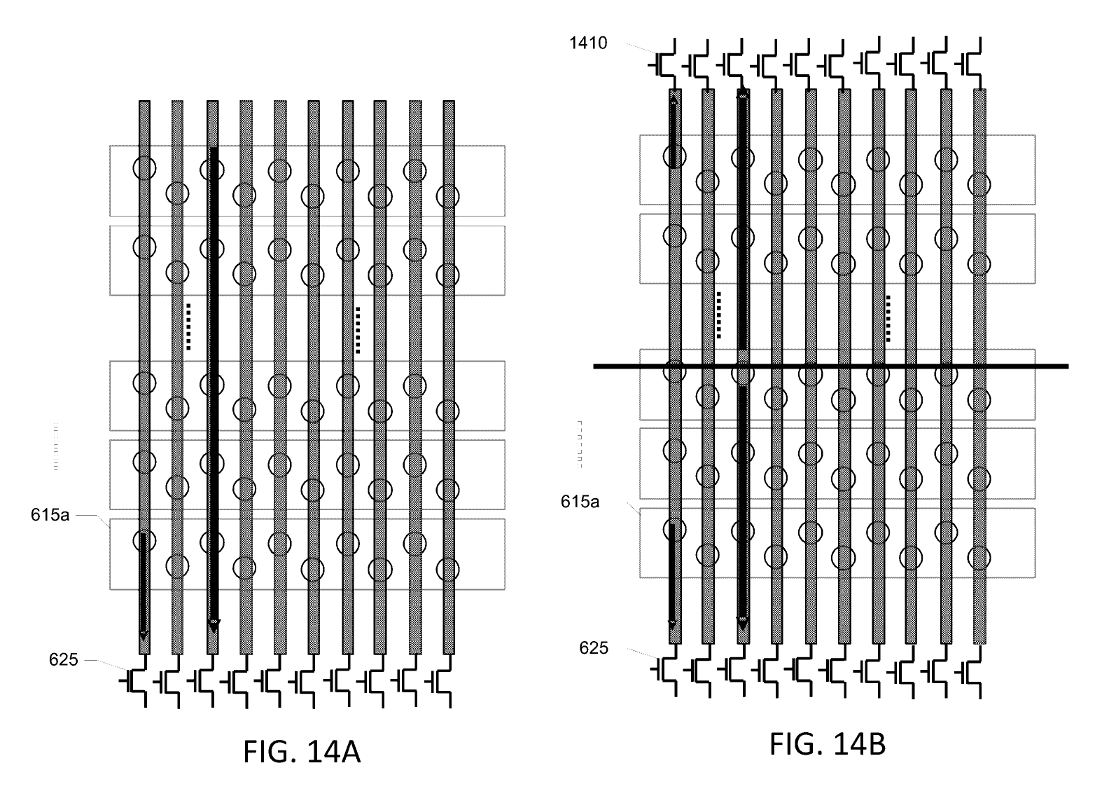

Furthermore, it should be understood that while the present invention is described for clarity using the a VC array, for example, positioned away from the S/A PB transistors 625, in some embodiments of the present invention, a second set of discharge transistors may be positioned on the other side of the memory array. For example, FIG. 14A shows a conventional architecture where SA PB transistors 625 are positioned on one side of the memory array, and FIG. 14B shows an embodiment in which discharging transistors 1410 may positioned on a different side (e.g., the opposite side of the original SA PB transistors 625) such that performing BL discharging may only require half the distance of the BLs.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

What is claimed is:

1. An apparatus for controlling a non-volatile memory device, the apparatus comprising:
a substrate; and
a 3D array of non-volatile memory cells, the 3D array including:
a plurality of blocks, each block comprising (1) a plurality of NAND strings of nonvolatile memory cells, each of plurality of NAND strings coupled to a bit line (BL); (2) one or more word lines, the one or more word lines arranged orthogonally to the plurality of NAND strings, the one more word lines establishing the nonvolatile memory cells at cross-points between surfaces of the plurality of NAND strings and the one or more word lines; and
a first set of discharge transistors, the first set of transistors positioned at an edge of the 3D array and coupled to a corresponding bit line, the first set of discharge transistors configured for BL discharge; and
a second set of discharge transistors, the second set of discharge transistors comprising one or more discharge transistors,
the second set of discharge transistors positioned such that a first portion of BL potential is discharged through the first set of discharge transistors and a second portion of BL potential is discharged through the second set of discharge transistors.

2. The apparatus according to claim 1, wherein the second set of discharge transistors couple a pre-defined NAND string to the substrate enabling discharging of the BL potential through the NAND string to the substrate.

3. The apparatus according to claim 1, wherein the second set of discharge transistors are coupled to a BL on a side opposite the first set of discharge transistors enabling discharging of the BL potential from both sides of the NAND string.

4. The apparatus according to claim 1, wherein the second set of discharge transistors is a single common transistor coupling the NAND string to the substrate enabling discharging of the BL potential through the NAND string to the substrate.

5. The apparatus according to claim 1, wherein the second set of discharge transistors is a plurality of discharging transistors, coupling each of a plurality of NAND string cells to the substrate enabling discharging of the BL potential through the NAND string to the substrate.

6. The apparatus according to claim 1, wherein the second set of discharge transistors is positioned at or near a mid-point of the BLs such that a maximum distance of the BL required for discharging is halved.

7. The apparatus according to claim 1, further comprising a third set of discharge transistors,
wherein the second set of discharge transistors is positioned at a far block or a side opposite the first set of discharge transistors and the third set of discharge transistors is positioned in a block at or near the middle of the memory array.

8. The apparatus according to claim 1, further comprising:
a control circuit configured for performing a bit line recovery operation in which the bit lines are discharged to a ground voltage level.

9. The apparatus according claim 1, wherein the non-volatile memory device comprises a NAND flash memory.

10. The apparatus according claim 1, wherein the 3D array includes one of a floating gate device or a charge trapping device.

11. A non-volatile memory device:
a 3D array of non-volatile memory cells, the 3D array including:
a plurality of blocks, each block comprising (1) a plurality of NAND strings of nonvolatile memory cells, each of plurality of NAND strings coupled to a bit line (BL); (2) one or more word lines, the one or more word lines arranged orthogonally to the plurality of NAND strings, the one more word lines establishing the nonvolatile memory cells at cross-points between surfaces of the plurality of NAND strings and the one or more word lines; and
a first set of discharge transistors, the first set of transistors positioned at an edge of the 3D array and coupled to a corresponding bit line, the first set of discharge transistors configured for BL discharge; and
a second set of discharge transistors, the second set of discharge transistors comprising one or more discharge transistors,
the second set of discharge transistors positioned such that a first portion of BL potential is discharged through the first set of discharge transistors and a second portion of BL potential is discharged through the second set of discharge transistors.

12. The nonvolatile memory device of claim 11, wherein the second set of discharge transistors couple a pre-defined NAND string to the substrate enabling discharging of the BL potential through the NAND string to the substrate.

13. The nonvolatile memory device of claim 11, wherein the second set of discharge transistors are coupled to a BL on a side opposite the first set of discharge transistors enabling discharging of the BL potential from both sides of the NAND string.

14. The nonvolatile memory device of claim 11, wherein the second set of discharge transistors is a single common transistor coupling the NAND string to the substrate enabling discharging of the BL potential through the NAND string to the substrate.

15. The nonvolatile memory device of claim 11, wherein the second set of discharge transistors is a plurality of discharging transistors, coupling each of a plurality of NAND string cells to the substrate enabling discharging of the BL potential through the NAND string to the substrate.

16. The nonvolatile memory device of claim 11, wherein the second set of discharge transistors is positioned at or near a mid-point of the BLs such that a maximum distance of the BL required for discharging is halved.

17. The nonvolatile memory device of claim 11, further comprising a third set of discharge transistors,
wherein the second set of discharge transistors is positioned at a far block or a side opposite the first set of discharge transistors and the third set of discharge transistors is positioned in a block at or near the middle of the memory array.

18. The nonvolatile memory device of claim 11, further comprising:
a control circuit configured for performing a bit line recovery operation in which the bit lines are discharged to a ground voltage level.

19. The nonvolatile memory device of claim 11, wherein the non-volatile memory device comprises a NAND flash memory.

20. A method of programming a nonvolatile semiconductor memory device, comprising:
providing a 3D array of non-volatile memory cells, the 3D array including:
a plurality of blocks, each block comprising (1) a plurality of NAND strings of nonvolatile memory cells, each of plurality of NAND strings coupled to a bit line (BL); (2) one or more word lines, the one or more word lines arranged orthogonally to the plurality of NAND strings, the one more word lines establishing the nonvolatile memory cells at cross-points between surfaces of the plurality of NAND strings and the one or more word lines; and
providing a first set of discharge transistors, the first set of transistors positioned at an edge of the 3D array and coupled to a corresponding bit line, the first set of discharge transistors configured for BL discharge; and
providing a second set of discharge transistors, the second set of discharge transistors comprising one or more discharge transistors,
the second set of discharge transistors positioned such that a first portion of BL potential is discharged through the first set of discharge transistors and a second portion of BL potential is discharged through the second set of discharge transistors; and
performing a bit line recovery operation in which the bit lines are discharged to a ground voltage level utilizing the first set of discharge transistors and the second set of discharge transistors.
